(19) United States
(12) Patent Application Publication
(10) Pub. No.: US 2026/0023111 A1
(43) Pub. Date: Jan. 22, 2026

(54) DIE RING SEQUENCER DEVICE AND METHOD THEREOF

(71) Applicant: Micron Technology, Inc., Boise, ID (US)

(72) Inventors: Kari Crane, Meridian, ID (US); Kevin G. Werhane, Kuna, ID (US); Maksim Kuzmenka, München (DE); Marc Walter, München (DE)

(21) Appl. No.: 19/268,924

(22) Filed: Jul. 14, 2025

Related U.S. Application Data
(60) Provisional application No. 63/672,684, filed on Jul. 17, 2024.

(51) Int. Cl. G01R 31/28; G01R 1/067

(52) U.S. Cl. CPC G01R 31/2879; G01R 1/06766; G01R 31/2856

(57) ABSTRACT

A semiconductor die defect detection device including a current mirror providing a first current on its first output and a second current on its second output, the first and second currents being identical, a swap circuit having a first terminal connected to the first output of the current mirror, a second terminal connected to the second output of the current mirror, a third terminal and a fourth terminal. The device also includes a die ring circuitry disposed at edges of the semiconductor die including a first plurality of segments disposed on a first leg of the die ring circuitry, and a second plurality of segments disposed on a second leg of the die ring circuitry. The device further includes a voltage comparator including a positive input terminal, a negative input terminal and an output terminal, and an adjustable resistor.

### CROSS-REFERENCE TO RELATED APPLICATION(S)

The present application claims priority to U.S. Provisional Patent Application No. 63/672,684, filed Jul. 17, 2024, the disclosure of which is incorporated herein by reference in its entirety.

### TECHNICAL FIELD

The present disclosure generally relates to semiconductor die ring sequencer device, and more particularly relates to a semiconductor die ring self-compare circuit for die defects detection.

### BACKGROUND

Integrated circuits are fabricated on semiconductor substrates using sophisticated manufacturing techniques. These circuits are produced on semiconductor wafers, which are subsequently divided into individual dies, each representing a distinct semiconductor device. These devices, potentially including memory units, multiprocessor systems, and power semiconductors, can be individually encased and integrated into broader electronic assemblies. With regards to memory devices, various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, and others. These are typically manufactured as integrated circuits on semiconductor dies, which are then sliced or separated from the semiconductor wafer.

During the “dicing” process or at other processes in the semiconductor manufacturing (e.g., during packaging of the die), mechanical stress may lead to open or short defects such as die cracks. For example, a dicing operation may produce stress on a respective edge of two dies cut from a single wafer. Such stress may lead to a crack in the respective edge of one or both of those dies. Detecting cracks and other defects on the semiconductor die can be a challenging process because many dies may be produced in a semiconductor manufacturing process, to which many stresses may be introduced. Visually inspecting the wafers for cracks in the die may be prohibitively slow and is not practical for volume production. Additionally, cracks in the die may not be visually apparent. For example, cracks may be only apparent under stress and become too small along a line feature and not easily detectable. Further, cracks may become larger under stress or with time. Accordingly, a need exists for detecting open and short defects in a die that may be scaled to account for volume production of dies.

### BRIEF DESCRIPTION OF THE DRAWINGS

FIG. 1 is a top-down view block diagram of an example semiconductor die layout in accordance with one or more embodiments of the present technology.

FIG. 2 shows an example die defect detection circuit in accordance with one or more embodiments of the present technology.

FIG. 3 shows a block diagram illustrating the coupling of stage logic blocks by signal lines of a semiconductor die according to one or more embodiments of the present technology.

FIG. 4 illustrates a block diagram of a die defect detection circuit connected with a semiconductor die for semiconductor die defect detection in accordance with one or more embodiments of the present technology.

FIGS. 5A and 5B show block diagrams of flowing mirror currents from the die defect detection circuit into segment lines of the semiconductor die in accordance with one or more embodiments of the present technology.

FIG. 6 shows example output signal waves from a voltage comparator of the die defect detection circuit in accordance with one or more embodiments of the present technology.

FIG. 7 shows a method flow of detecting semiconductor die defects in accordance with one or more embodiments of the present technology.

FIG. 8 shows a semiconductor die defects detection pre-conditioning method flow in accordance with one or more embodiments of the present technology.

FIG. 9 shows another method flow of detecting semiconductor die defects in accordance with one or more embodiments of the present technology.

FIG. 10 is a schematic block diagram of a system that includes a semiconductor device configured in accordance with one or more embodiments of the present technology.

### DETAILED DESCRIPTION

In semiconductor devices, such as DRAM and NAND memory device, the integrity of a semiconductor die is important for ensuring long-term functionality and reliability. To prevent defects such as shorts and opens on semiconductor die, a specialized circuit known as the die ring can be integrated into the semiconductor die or devices. The primary function of the die ring is to detect cracks that may occur along the semiconductor die's edge. These cracks are typically a result of the dicing and packaging processes and pose a significant risk as they have the potential to expand over time. If not uncovered, such crack defects can traverse the entire die or impact the functional circuitry, leading to device failure. Moreover, the die ring serves a crucial role in the early detection of process marginalities. This allows for the identification of potential issues even before the wafer is singulated for packaging. By catching these defects early, it is possible to mitigate risks that could otherwise lead to significant yield losses or device performance degradation.

Alongside the die ring test, customers often encounter difficulties in reading out the test results when the device is in a system or an application environment. One of the primary challenges is the inability to strobe or capture the output effectively. For example, customers may only have access to a digital die crack test, which limits their testing capabilities to a binary digital output that indicates the presence or absence of a crack. As a common trade off in the industry, this digital test lacks the ability to run an analog-based test, which is more sensitive and can detect partial opens or shorts that might not trigger a digital response. To address this limitation, certain new features have been implemented to separate the customer flag from the internal flag, allowing the flag to be loaded into a mode register to facilitate customer readout. However, customers are still required to activate a sequence of test modes to extract the defect test result with these improvements. Further, customers are limited to running the digital test, which utilizes a series of latches around the die to output a flag, meaning the digital test is inherently less sensitive to shorts and partial opens. In contrast, an analog-style test can be conducted during production testing, but this approach requires a statistical analysis of a large number of dies in order to set pass and fail limits.

To solve the issues and challenges described above, the present technology introduces a new die-ring circuit for the semiconductor die defects detection. This circuit employs a resistance comparison technique based on a symmetrical semiconductor die layout, where the die-ring segments are of equal length and arranged in a mirrored configuration on the semiconductor die (e.g., along the semiconductor die's perimeter). Specifically, the novel circuit leverages the symmetrical die-ring structure to compare two resistances of the symmetrical segments using a voltage comparator and subsequently outputting a digital signal. In addition, the circuit architecture includes a current mirror to distribute currents evenly across the die-ring segments, a swap circuit, and an adjustable resistance connected to the comparator's positive input terminal. This setup enables an on-die analog test that self-compares and generates a digital result. Another significant feature of the present technology is the automated sequencing of both digital and analog die-ring tests. This allows users to initiate the testing mode with a single command and obtain a pass/fail status through a simple readout. The mirrored segment arrangement is a key benefit that enhances the self-comparison capability of the new die-ring circuit. Further advancements in the present technology can be achieved by integrating a state machine to proceed a sequence of operations required for running in a customer mode. Additionally, the present technology can incorporate existing die crack detection circuits, optimizing for size, cost, and routing efficiency. While the technology is particularly beneficial for DRAM circuits, it is also applicable to other semiconductor chips such as System on a Chip (SoC) and NAND flash memory chips.

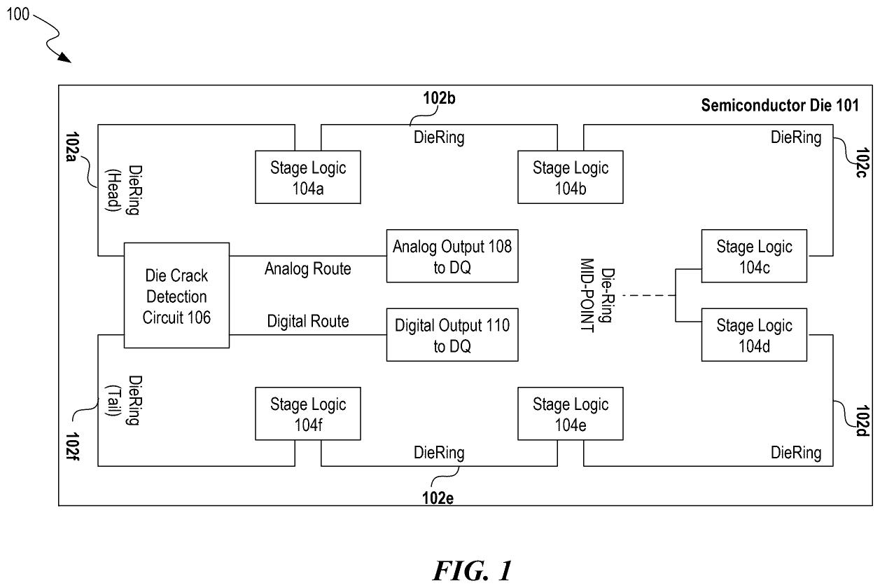

FIG. 1 is a top-down view block diagram of an example die layout 100 in accordance with one or more embodiments of the present technology. The die layout 100 includes a semiconductor die 101 on which circuits can be fabricated. The die 101 includes test segment circuits or stage logic blocks 104a-104f, and a die crack detection circuit 106. The die 101 also includes segment lines 102a-102f, each of which is coupled between corresponding stage logic blocks of the stage logic blocks 104a-104f. The die crack detection circuit 106 may be configured to test for die cracks by driving voltages to stage logic blocks 104a-104f along the segment lines 102a-102f. One of the segment lines coupled to the die crack detection circuit 106 (e.g., the segment line 102a) may be referred to as a head segment line of a first leg of the die layout 100 and another segment line coupled to the die crack detection circuit 106 (e.g., the segment line 102f) may be referred to as a tail segment line of a second leg of the die layout 100. As shown in FIG. 1, the first leg and second leg of the die layout 100 is symmetrical, e.g., along the line of the die-ring mid-point. In this example, the stage logic blocks 104a-104f may be configured to control an operation performed on a segment line coupled to a respective stage logic block. For example, the stage logic block 104a may control a test operation performed on the head segment line 102a and the segment line 102b; the stage logic block 104b may control a test operation on the segment line 102b and the test segment line 102c; and so on.

With the stage logic blocks 104a-104c formed along the upper half of the die 101 coupled via the segment lines 102a-102c as well as the stage logic blocks 104d-104f formed along the lower half of the die 101 coupled via the segment lines 102d-102f, semiconductor die defects such as die cracks may be detected along each segment lines of the upper half or lower half of the die 101. Such horizontal segmentation across the edges of the die 101 may allow more efficient testing of die cracks and more accurately identify the location of any die cracks that are found. With increased accuracy of the location of a crack, scribe features used in forming and characterizing the circuits of the die may be analyzed at a corresponding location to determine if the scribe feature is the cause of the die cracks being formed. Once the cause is determined, data including the scribe feature can be feedback to the semiconductor chip manufacturing processes and/or assembly processes for further corrections and optimizations. Such a process of detecting die cracks can avoid further die cracks from being caused in other dies using the same scribe feature. Accordingly, the die layout 100 may be utilized in dies to detect die cracks formed in the die 101, for example, die cracks generated when dicing through a specific scribe feature, by the manufacturing process of the die 101 (e.g., blade dicing, laser cutting, etching), or by some other irregularity in the die 101.

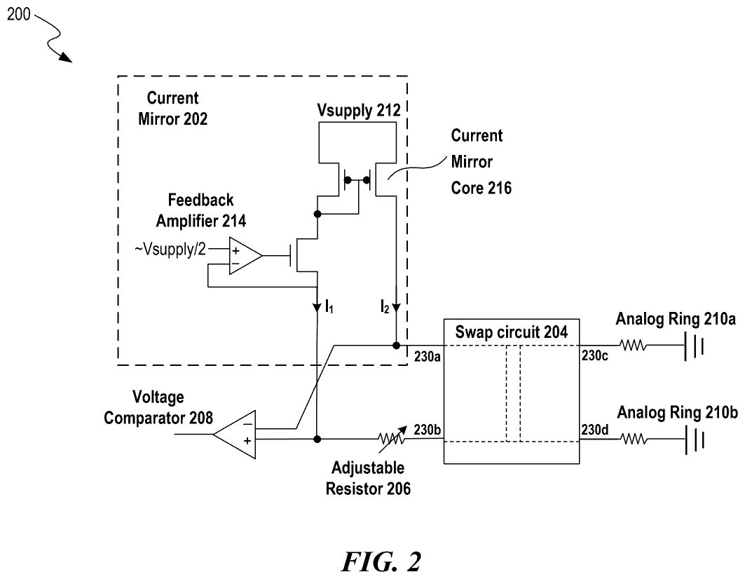

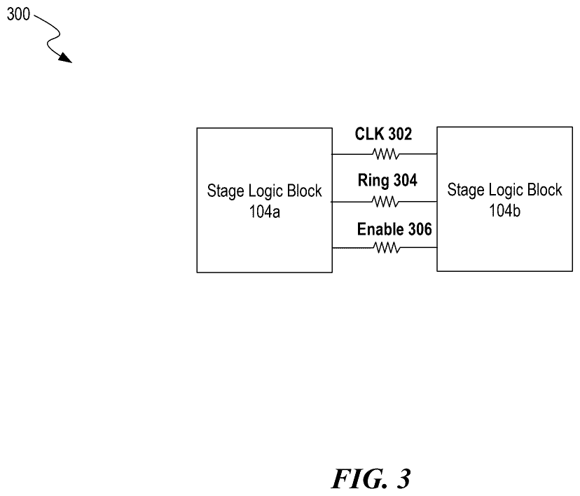

As will be apparent from the description below, the test operations of the stage logic blocks may be utilized to control an operation on corresponding segment lines coupled thereon. The stage logic blocks may be operated in conjunction with the die crack detection circuit 106 to determine whether die cracks exist along the upper half or lower half of the die 101. The components of a stage logic blocks 104a-104f and die crack detection circuit 106 may be made up of circuitry designed to carry out their functions. This may include various circuit elements, for example, conductive lines, transistors, capacitors, inductors, resistors, amplifiers, or other active or inactive elements, configured to carry out the functions described herein. An example embodiment, stage logic blocks 104a-104f are described herein with respect to FIGS. 3, 4, 5A and 5B. An example embodiment of a die crack detection circuit 106 is described herein with respect to FIGS. 2, 4, and 5A and 5B.

As shown in FIG. 1, the example die layout 100 also includes a digital output block 110 providing digital sense route signal and analog enable signal to the die ring segments through the die crack detection circuit 106. In addition, the example die layout 100 includes an analog output block 108 providing analog signals to the die ring segments through the die crack detection circuit 106.

FIG. 2 illustrates an example die defect detection circuit 200 in accordance with one or more embodiments of the present technology. In particular, the die defect detection circuit 200 can be the die crack detection circuit 106 described in FIG. 1. In this example, the die defect detection circuit 200 includes a current mirror 202 that comprising a current mirror core 216, a voltage supply 212 connected to the current mirror core 216, and a feedback amplifier 214 having a negative input terminal connected to a first current output hi of the current mirror core 216. The feedback amplifier 214 also has a positive input terminal connected to a voltage supply 214 providing a voltage about half of that of the voltage supply 212. For example, the voltage supply 212 may provide a first voltage close to 1.2V and the voltage supply 214 may provide a second voltage close to 0.5V. In some other examples, the voltage supply 212 may provide a voltage up to 2V and the voltage supply 214 may provide a voltage up to 1V. In addition, the current mirror core 216 may comprises a differential amplifier circuit.

In this example, the die defect detection circuit 200 also includes a swap circuit 204 having a first terminal 230a, a second terminal 230b, a third terminal 230c, and a fourth terminal 230d. The swap circuit 204 may include a multiplexer that adjusts the interconnections between the pair of the first and second terminals 230a-230b and the pair of the third and fourth terminals 230c-230d. For example, the first terminal 230a can be electrically connected to the third terminal 230c and the second terminal 230b can be electrically connected to the fourth terminal 230d. In some other examples, the first terminal 230a can be electrically connected to the fourth terminal 230d and the second terminal 230b can be electrically connected to the third terminal 230c.

Further, the die defect detection circuit 200 includes a voltage comparator 208 having a positive input terminal, a negative input terminal, and an output terminal. As shown in FIG. 2, the negative input terminal of the voltage comparator 208 and the first terminal 230a of the swap circuit 204 are interconnected, further connecting to a second current output I₂ of the current mirror core 216 of the current mirror 202. In this example, the first and second current outputs I₁ and I₂ of the current mirror core 216 are identical to each other. The die defect detection circuit 200 also includes an adjustable resistor 206 that interconnects the positive input terminal of the voltage comparator 208 and the second terminal 230b of the swap circuit 204. Here, the adjustable resistor 206 can be made of passive elements in incremental values and has a resistance ranging from 1K ohms to 100K ohms. In some other examples, the adjustable resistor 206 can have a resistance ranging from 0.5% to 40% of resistance of corresponding analog ring.

As shown in FIG. 2, the example die defect detection circuit 200 can be connected to a pair of symmetrical analog die rings for die defect measurement. Specifically, the third terminal 230c and the fourth terminal 230d can be respectively connected to an analog ring 210a and an analog ring 210b for the test. Here, analog ring 210a and an analog ring 210b are in symmetrical (e.g., have similar layout and design on die ring electronic components) and can each represent one or more segment lines described in FIG. 1. In another example, the swap circuit 204 may include more terminals connected to additional analog rings that are parallelly aligned on the semiconductor chip. For example, the swap circuit 204 may include a fifth terminal and a sixth terminal that are respectively connected to a third analog ring and a fourth analog ring. The first terminal 230a and the second terminal 230b can be electrically connected to one pair of terminals from the third terminal 230c, the fourth terminal 230d, the fifth terminal and the sixth terminal, wherein the analog rings connected to the one pair of terminals are parallelly disposed on the semiconductor chip. In some other examples, there may be more than two pairs of analog rings, e.g., 3 pairs or more, that are connected to the swap circuit 204. Accordingly, the swap circuit 204 may included additional terminals, e.g., up to 8 terminals or more, to support the interconnections between the semiconductor chip and the die defect detection circuit 200.

In one example, the die defect detection circuit 200 can be configured to deliver the current I₁ to the analog ring 210b, through the adjustable resistor 206 and the second terminal 230b and the fourth terminal 230d of the swap circuit 204. In meanwhile, the die defect detection circuit 200 can deliver the current I₂ from the current mirror 202 to the analog ring 210a, through the first terminal 230a and the third terminal 230c of the swap circuit 204. With this configuration, the voltage input to the positive input terminal of the voltage comparator 208 can be higher than that on the negative input terminal because the analog ring 210b in combination with the adjustable resistor 206 has a higher resistance in comparison to the analog ring 210a. This configuration can be used to test the die defect along the path of analog ring 210a. For example, when the voltage input at the positive input terminal of the voltage comparator 208 is equal to or lower than that on the negative input terminal, an open defect can be identified on the path of the analog ring 210a with a fail signal generated at the output terminal of the voltage comparator 208. Moreover, if a short defect exists on the analog ring 210b and the adjustable resistor 206 is configured to have a resistance lower than the analog ring 210a, the voltage input to the positive input terminal of the voltage comparator 208 will be lower than that on the negative input terminal, generating a fail signal on the output terminal of the voltage comparator 208.

In other examples, the die defect detection circuit 200 can be configured to deliver the current I₁ to the analog ring 210a, through the adjustable resistor 206 and the second terminal 230b and the third terminal 230c of the swap circuit 204. In meanwhile, the die defect detection circuit 200 can deliver the current I₂ from the current mirror 202 to the analog ring 210b, through the first terminal 230a and the fourth terminal 230d of the swap circuit 204. With this configuration, the voltage input to the positive input terminal of the voltage comparator 208 can be higher than that on the negative input terminal because the analog ring 210a in combination with the adjustable resistor 206 has a higher resistance in comparison to the analog ring 210b. This configuration can be used to test the die defect along the path of analog ring 210b. For example, when the voltage input at the positive input terminal of the voltage comparator 208 is equal to or lower than that on the negative input terminal, an open defect can be identified on the path of the analog ring 210b with a fail signal generated at the output terminal of the voltage comparator 208. Moreover, if a short defect exists on the analog ring 210a and the adjustable resistor 206 is configured to have a resistance lower than the analog ring 210b, the voltage input to the positive input terminal of the voltage comparator 208 will be lower than that on the negative input terminal, generating a fail signal on the output terminal of the voltage comparator 208.

The resistance of segment lines on the path of analog ring 210a and the path of analog ring 210b varies and relates to a number of segment lines in each of the analog ring paths. For example, if there is one segment line in each of the analog ring 210a and analog ring 210b, the resistance of each of the analog ring 210a and analog ring 210b maybe up to 500K ohms. In other example, the resistance of each of the analog ring 210a and analog ring 210b can be higher than 500K ohms. In some other examples, if there are four segment lines in each of the analog ring 210a and analog ring 210b, the resistance of each of segment line along the analog ring 210a and analog ring 210b maybe up to 100K ohms. In this example, the adjustable resistor 206 can be configured to provide a resistance up to 100K ohms. In particular, the adjustable resistor 206 can provide a resistance close to 2K ohms, 5K ohms, 10K ohms, 15K ohms, or 40K ohms.

In some examples, the present technology provides a novel die defect detection circuit 200 that combines a self-compare analog style test with digital controls and a digital output. This circuit 200 enables easy access for a customer and eliminates the need to characterize large distributions of parts to detect die opens/shorts. Moreover, the circuit 200 avoids the error caused by leaky and resistive circuitry from the Signals-Out path to the bond pad through the tester hardware, which typically must be normalized out of the measurements to get an accurate result.

For example, the die defect detection circuit 200 can utilize the digital paths from the existing die ring, but inject the digital paths to both sides of the die ring simultaneously, allowing a self-compare operation if the segments are of equal length. The circuit 200 replaces the digital output digital output (e.g., 110 of FIG. 1) with the output from the voltage comparator 208. As shown in FIG. 2, the circuit 200 operates by having trace lengths (segments) with approximately equal resistance and the same current running through them and pulled to ground on the opposite end. The effective voltage generated from each leg is then compared against each other by the voltage comparator 208. The swap circuit 204 and the adjustable resistor 206 are also included in the circuit 200. The adjustable resistor 206 is made using passive elements in incremental values, for example 2K, 5K, 10K, or 50K ohms etc. Both ends of the segments lead into a swap circuit 204, on the other end of the swap circuit 204 a small added resistance from the adjustable resistor 206, for example 2K ohms, is attached to the positive terminal of the comparator 208. This configuration makes the positive side have a higher voltage if there are no cracks and the comparator's output will pulse high for a pass. Then the segments compared on one side of the ring will swap and the added resistance stays on the input of the positive end of the comparator 208, making the passing state still high. In this example, the adjustable resistor 206 is configured to provide an adjustable threshold for the circuit to control the level at which the difference between the resistance or voltage of the two segments will result in a fail. The maximum variable resistance values were determined based on half the smallest die ring segment resistance of approximately 100K ohms and will be reviewed against silicon data when available.

FIG. 3 is a block diagram 300 illustrating the coupling of stage logic blocks 104a and 104b through signal lines of the die 101 according to an embodiment of the present technology. In the example diagram 300, each of the signal lines of the die 101 are depicted and corresponds to a conductive path through one or more physical layers of the die 101. As depicted in FIG. 3, conductive paths may travel through various layers of the die 101. In this example, the die 101 includes three signal lines, each signal line being coupled to adjacent stage logic blocks on the die 101 and configured to control a test operation among segment lines of the die 101. For example, the die crack detection circuit 106 may control a test operation along head segment line 102a and test segment lines 102b and 102c, which may represent the segment lines disposed on upper half of the die 101. In this example, the stage logic blocks 104a-104c may be coupled to each other via a portion of each of the signal lines described herein. Here, the signal lines include a digital clock signal line 302, an analog route/ring signal line 304, and a digital enable signal line 306.

In some examples, a DRAM die ring is implemented as a set of 3 stacked wires that go around the border of the die 101 and serpentine up and down vertically from a poly silicon layer up to a M5 layer in the die layout 100. The top wire is used as a clock signal 302, the middle wire as an analog sense route 304, and the lowest wire is for an enable signal 306. In the digital test, the clock signal 302 and the enable signal 306 can be sent from the digital output block 110 through the entire ring, turning on each stage logic. Moreover, the analog sense route 304 can be sent from the analog output block 108 through the entire die ring of die 101.

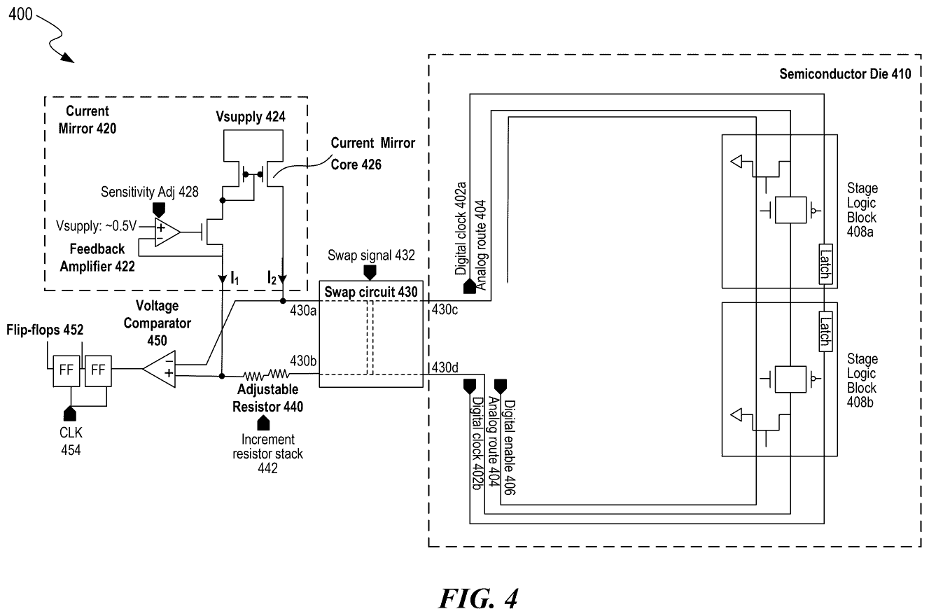

FIG. 4 illustrates a block diagram of a die defect detection circuit 400 connected with a semiconductor die 410 for semiconductor die defect detection in accordance with one or more embodiments of the present technology. As shown, the die defect detection circuit 400 has a similar design to the die defect detection circuit 200 described in FIG. 2. For example, the die defect detection circuit 400 includes a current mirror 420 that comprising a current mirror core 426, a voltage supply 424 connected to the current mirror core 426, and a feedback amplifier 422 having a negative input terminal connected to a first current output hi of the current mirror core 426. The die defect detection circuit 400 also includes a swap circuit 430 having four terminals 430a-430d. The interconnections among the four terminals 430a-430d are similar to that of the four terminals of 230a-230d described in FIG. 2. In addition, the die defect detection circuit 400 includes an adjustable resistor 440 and a voltage comparator 450. The interconnection and configurations of the current mirror 420, swap circuit 430, adjustable resistor 440, and the voltage comparator 450 are similar to the corresponding components of the die defect detection circuit 200 of FIG. 2. In this example, the die defect detection circuit 400 further includes one or more flip flops circuit 452 that are configured to store the output signals from the voltage comparator 450.

In this example, metal routings such as segments can be disposed around edge of the semiconductor die 410. As shown in FIG. 4, the semiconductor die 410 includes an upper segment disposed on the upper half of the semiconductor die 410 and a lower segment dispose on the bottom half of the semiconductor die 410. The upper and lower segments are respectively connected with the stage logic block 408a and 408b respectively. In this example, the stage logic blocks 408a and 408b perform similar functions to the stage logic blocks 104a-104f described in FIG. 1, e.g., to control a test operation performed on the segment line coupled thereon. Similar to the interconnection signals lines 302-306 disclosed in FIG. 3, the digital clock signal lines 402a and 402b, analog route 404 and digital enable signal line 406 are disposed on the semiconductor die 410 and electrically connected to the stage logic blocks 408a and 408b. In addition, each of the stage logic blocks 408a and 408b includes a latch circuit, an isolation circuit, and a pull down circuit. As shown in FIG. 4, the latch circuit of each of the stage logic blocks 408a and 408b is connected to the corresponding digital clock signal line 402. Additionally, the isolation circuit and the pull down circuit of each of the stage logic blocks 408a and 408b is connected to the corresponding analog route 404.

In some other examples, the current mirror 420, specifically its current outputs I₁ and I₂ can directly flow to the segment lines of the semiconductor die 410. For example, the outputs of the current mirror core 426 can be directly connected to the analog route 404 of the semiconductor 410. For example, the mirror currents I₁ or I₂ can flow through one of the upper or lower segment lines of the semiconductor 410 and toward the voltage comparator 450. One of the mirror currents I₁ and I₂ can further flow through the adjustable resistor 440.

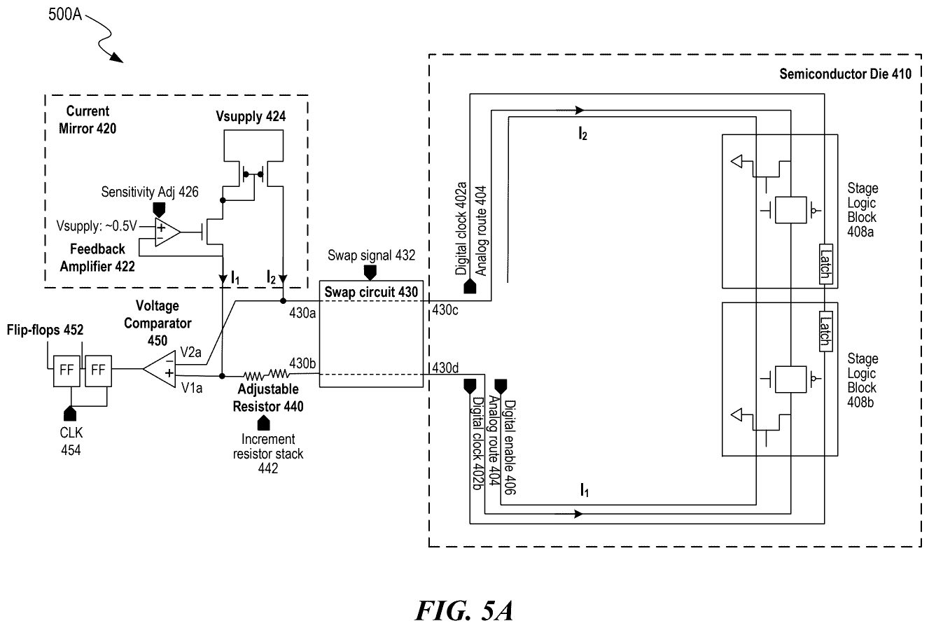

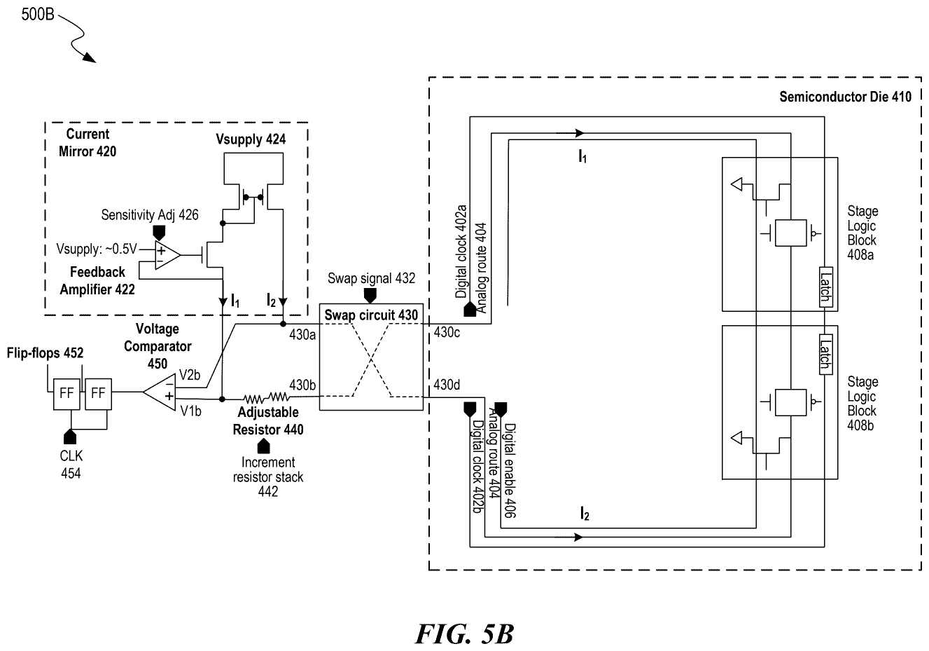

As shown in FIG. 4, the die defect detection circuit 400 is connected with the semiconductor die 410 through connecting the third and fourth terminals 430c and 430d of the swap circuit 430 to corresponding segments of the semiconductor die 410. Mirror currents I₁ and I₂ are configured to flow into various segment lines of the semiconductor die 410 based on the configuration of terminal interconnection of the swap circuit 430. For example, FIG. 5A shows a block diagram 500A having the mirror current I₁ and I₂ flowing into the lower segment line (e.g., bottom portion of the analog route 404) and the upper segment line (e.g., upper portion of the analog route 404), respectively. Here, the control on mirror currents I₁ and I₂ is conducted by interconnecting the first and third terminals 430a and 430c and interconnecting the second and fourth terminals 430b and 430d of the swap circuit 430. With this configuration, the current I₁ flow through the adjustable resistor 440 and the lower segment line of the semiconductor die 410. As a result, a first test voltage applied on the adjustable resistor 440 and the lower segment line of the semiconductor die 410 is provided to the positive input terminal of the voltage comparator 450. In comparison, a second test voltage applied on the higher segment line of the semiconductor die 410 is provided to the negative input terminal of the voltage comparator 450. In this example, the voltage comparator 450 is configured to compare the first test voltage and the second test voltage, and output a pulse signal (e.g., as a pass) when the first test voltage is higher than the second test voltage. When the upper segment line has an open defect (e.g., a die crack), the second test voltage may be much higher than the first test voltage, indicating an infinite resistance on the upper segment line. As a result, the voltage comparator 450 generates a low signal (e.g., as a fail). As shown, the output signals of the voltage comparator 450 is stored in the one or more flip-flops circuit 452.

In another example, FIG. 5B shows a block diagram 500B having the mirror current I₁ and I₂ flowing into the upper segment line (e.g., upper portion of the analog route 404) and the lower segment line (e.g., bottom portion of the analog route 404), respectively. Here, the control on mirror currents I₁ and I₂ is conducted by interconnecting the first and fourth terminals 430a and 430d and interconnecting the second and third terminals 430b and 430c of the swap circuit 430. With this configuration, the current I₁ flow through the adjustable resistor 440 and the upper segment line of the semiconductor die 410. As a result, a third test voltage applied on the adjustable resistor 440 and the upper segment line of the semiconductor die 410 is provided to the positive input terminal of the voltage comparator 450. In comparison, a fourth test voltage applied on the lower segment line of the semiconductor die 410 is provided to the negative input terminal of the voltage comparator 450. In this example, the voltage comparator 450 is configured to compare the third test voltage and the fourth test voltage, and output a pulse signal (e.g., as a pass) when the third test voltage is higher than the fourth test voltage. When the lower segment line has an open defect (e.g., a die crack), the fourth test voltage may be much higher than the third test voltage, indicating an infinite resistance on the lower segment line. As a result, the voltage comparator 450 generates a low signal (e.g., as a fail). Similar to that of the FIG. 5A, the output signals of the voltage comparator 450 is stored in the one or more flip-flops circuit 452.

FIGS. 5A and 5B illustrate example semiconductor dies that include a single segment line on its upper and lower halves. It will be appreciated that similar configuration and die defect detection can be applied on semiconductor die have multiple segment lines disposed symmetrically on the upper and lower halves of the semiconductor die. In this example, a portion of the multiple segment lines disposed symmetrically on the upper or lower halves of the semiconductor die can be tested. For example, each of the upper and lower halves of the semiconductor die 410 may include four segment lines. The first segment line of each of the four segment lines disposed the upper and lower halves of the semiconductor die 410 can be tested using the procedures described above. In addition, two segment lines (e.g., the first and second segment lines) of each of the four segment lines disposed the upper and lower halves of the semiconductor die 410 can be tested. Similarly, three segment lines (e.g., the first, second, and third segment lines) of each of the four segment lines disposed the upper and lower halves of the semiconductor die 410 can be tested. The inclusion of segment lines on the semiconductor die 410 for the die defect detection can be configured through adjusting the digital clock signal 402 and the digital enable signal 406.

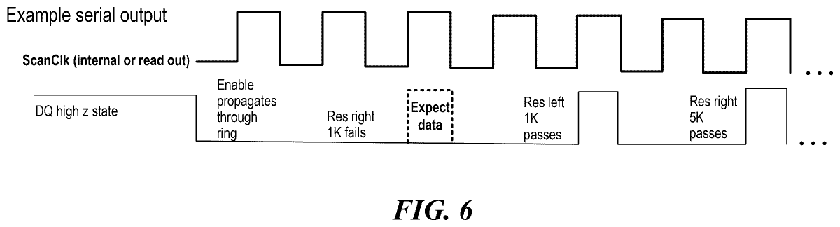

FIG. 6 shows an example output signal waves from the voltage comparator 450 in accordance with one or more embodiments of the present technology. As shown, an enable signal takes the output from a high Z state to low state to begin the voltage comparison results output. The DQ signal wave has high pulses for each of the consecutive passes. For example, it includes a low state when the resistor (e.g., the adjustable resistor 440) is configured to be 1K ohms with a first interconnection setup on the swap circuit 430. The low state (corresponding to labeled expect data pulse) indicates that the test is failed and a defect such as a die crack exists on one of the segment lines disposed on test semiconductor die. In comparison, the wave form also includes a high state when the resistor is configured to be 1K ohms with a second interconnection setup on the swap circuit 430. The high pulse indicates that the test passes and the positive input terminal of the voltage comparator 450 receives a higher voltage than that of the negative input terminal. In addition, the die defect test can be propagated through the die ring by adjusting the resistor resistance from a low value to high values and generate output signals in serial. For example, the DQ signal wave includes a high pulse indicating the semiconductor die passes the test when the resistor is adjusted to be close to 5K ohms.

The output signals of the voltage comparator 450 can be stored in the flip-flop circuits/registers 452. In some examples, the flip-flop circuits 452 include AND gates for MR readout. For example, enable flags can be stored in MR bit[0] as “0” for a pass. In addition, the 1K test output signal can be stored in MR bit[1] as “1” for a pass and “0” for a fail. Similarly, the 5K test output signal can be stored in MR bit[2] as “1” for a pass and “0” for a fail.

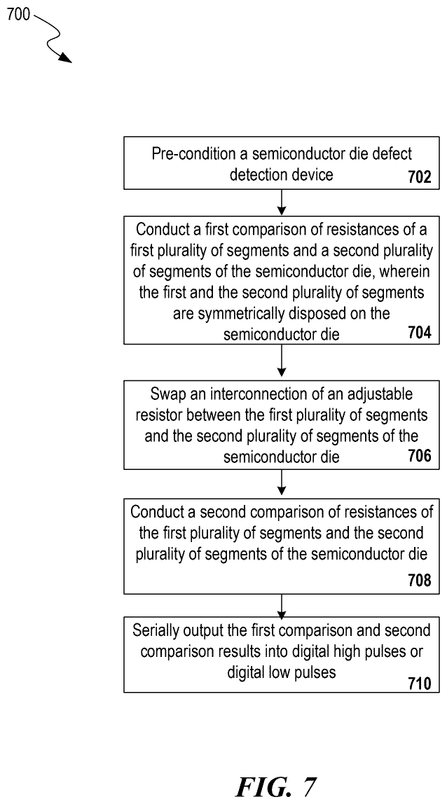

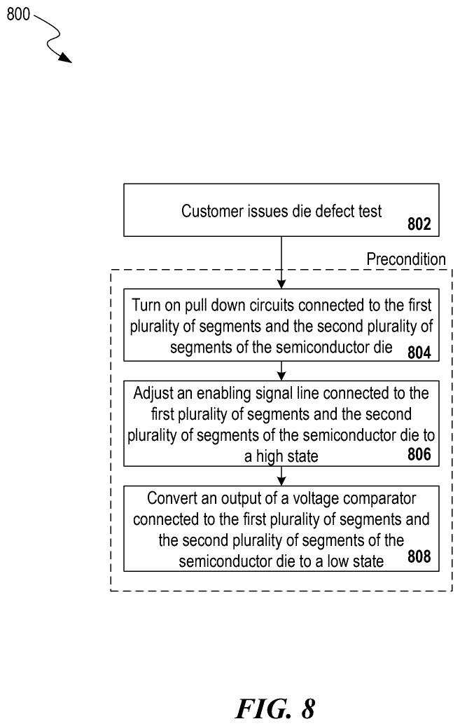

FIG. 7 shows a method (sequence flow) 700 of detecting semiconductor die defects in accordance with one or more embodiments of the present technology. The method 700 includes pre-conditioning a semiconductor die defect detection device, at 702. For example, FIG. 8 shows a method flow 800 of pre-conditioning for a die defect detection test. Once a customer issues the die ring test at 802, the die defect detection pre-conditioning starts. It firstly turns on pull down circuits connected to the first plurality of segments and the second plurality of segments of the semiconductor die, at 804. And then the pre-conditioning adjusts an enabling signal line connected to the first plurality of segments and the second plurality of segments of the semiconductor die to a high state, at 806. After that, an output of a voltage comparator connected to the first plurality of segments and the second plurality of segments of the semiconductor die is converted to a low state, at 808.

The method 700 also includes conducting a first comparison of resistances of a first plurality of segments and a second plurality of segments of the semiconductor die, wherein the first and the second plurality of segments are symmetrically disposed on the semiconductor die, at 704. For example, the adjustable resistor 440 can be adjusted to a first resistance such as 2K ohms. The adjustable resistor can be connected with the second plurality of segments of the semiconductor die such as the lower segment lines of the semiconductor die 410 shown on FIG. 5A. The mirror currents I₁ and I₂ can flow respectively to the lower and upper segment lines of the semiconductor die 410, respectively. Following the test, a first voltage applied on upper segment lines of the semiconductor die 410 can be input to a negative input terminal of the voltage comparator 450 and a second voltage applied on the adjustable resistor 440 and the lower segment lines of the semiconductor die 410 can be input to a positive input terminal of the voltage comparator 450.

In addition, the method 700 includes swapping an interconnection of an adjustable resistor between the first plurality of segments and the second plurality of segments of the semiconductor die, at 706. For example, the interconnections of swap circuit 430 terminals can be adjusted, as shown in FIGS. 5A and 5B. In this example, the first terminal 430a can be connected to the fourth terminal 430d and the second terminal 430b can be connected to the third terminal 430c, as shown in FIG. 5B. With this configuration, the adjustable resistor 440 is connected with the upper segment lines of the semiconductor die 410 in serial.

The method 700 also includes conducting a second comparison of resistances of the first plurality of segments and the second plurality of segments of the semiconductor die, at 708. For example, after the terminal interconnect is configured as shown in FIG. 5B, mirror currents I₁ and I₂ can flow respectively to the upper and lower plurality of segment lines on the semiconductor die 410. Following the test, a third voltage applied on the adjustable resistor 440 and the upper segment lines is input to the positive input terminal of the voltage comparator 450. In addition, a fourth voltage applied on the lower segment lines of the semiconductor die 410 is input to the negative input terminal of the voltage comparator 450.

Lastly, the method 700 includes serially outputting the first comparison and second comparison results into digital high pulses or digital low pulses, at 710. For example, voltage comparison results generated from above testing illustrated on FIGS. 5A and 5B can be output in digital formats (e.g., high pulse or low state) and stored in the flip-flop circuits 452.

The present technology can proceed the method 700 by operating a state machine, e.g., inputting customer commands to the die defect detection circuit inputs including the feedback amplifier sensitivity adjustment input terminal 428, swap signal input terminal 432, increment resistor stack input terminal 442, and flip-flop clk input terminal 454, to perform a customer issued die ring test following a specific sequence. Depending on a specific test mode configuration, the customer commands can be toggled to map to various internal test mode addresses.

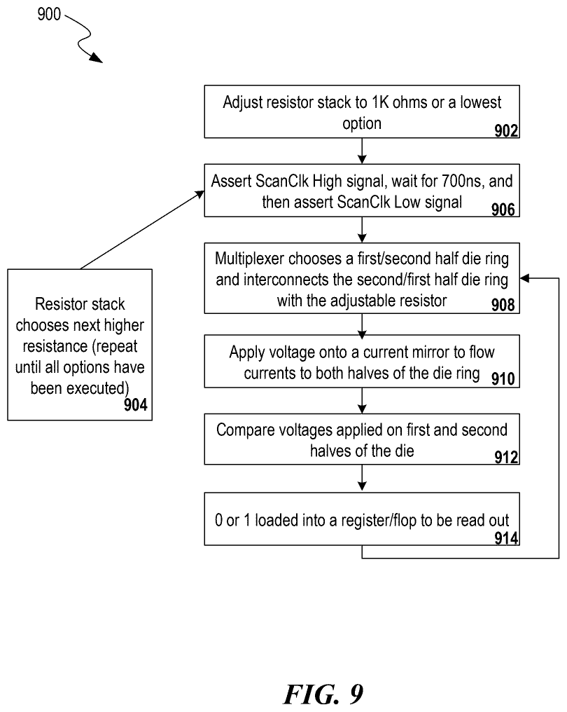

FIG. 9 illustrates another flow of method 900 for semiconductor die defect detection according to one or more embodiments of the present technology. For example, the method 900 includes adjusting resistance value of the adjustable resistor 440 to its lowest option, e.g., 1K ohms, at 902. Then the die defect detection circuit 200 asserts a ScanClk high signal and a ScanClk low signal with a 700 ns interim period, at 906. In a next step, the swap circuit 430 can be configured to connect the adjustable resistor 440 in serial with one of the upper or lower segment lines of the semiconductor die 410, at 908. After that, a target voltage, e.g., close to 1.2V, can be applied on the current mirror core 426 of the current mirror 420, to flow mirrored current I₁ and I₂ to the upper and lower halves (upper and lower segment lines) of the semiconductor die 410, at 910. Here, a feedback amplifier, such as the feedback amplifier 422, can be connected to the current mirror core 426 to keep the voltage on the positive node of the voltage comparator 450 at a target value. In a next step, the voltage applied on the upper and lower halves of the semiconductor die 410 are compared at the voltage comparator 450, at 912. Digital comparison results such as “0” or “1” can be output from the voltage comparator 450 and stored at/readout through the flip-flop circuits/registers 452, at 914. In a following sequence of the defect test, the swap circuit 430 can be reconfigured to adjust the interconnection of the adjustable resistor 440 with one of the upper and lower segment lines of the semiconductor die 410, at 908. After that the test sequence described in steps 910-914 can be repeated. Further, the resistance of the adjustable resistor 440 can be adjusted to a next resistance such as 2K ohms, at 904. The test steps shown in FIG. 9 can be repeated until all resistance options of the adjustable resistor have been executed.

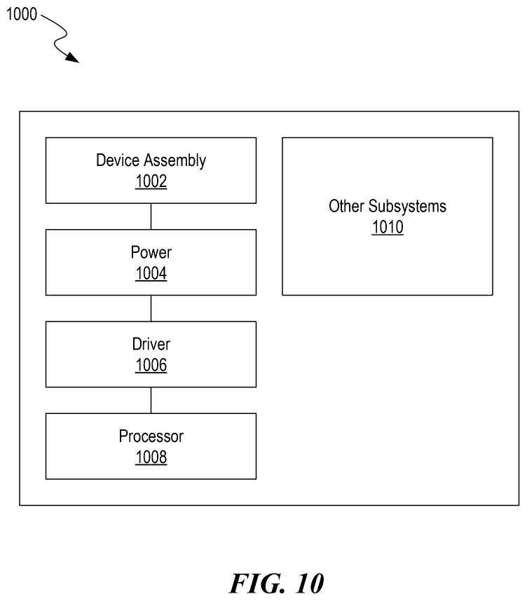

Any one of the semiconductor die defect detection circuits and methods for die defect detection described above with reference to FIGS. 1 to 9 can be incorporated into any of a myriad of larger and/or more complex systems (e.g., semiconductor chips having 2 or more sets of paired ring segments/legs, or a SoC), a representative example of which is system 1000 shown schematically in FIG. 10. The system 1000 can include a semiconductor device assembly (e.g., or a discrete semiconductor device) 1002, a power source 1004, a driver 1006, a processor 1008, and/or other subsystems or components 1010. The semiconductor device assembly 1002 can include features generally similar to those of the semiconductor die defect detection circuits described above with reference to FIGS. 1 to 9. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor die defect detection device, comprising:
a current mirror providing a first current on its first output and a second current on its second output, the first and second currents being identical;
a swap circuit having a first terminal connected to the first output of the current mirror, a second terminal connected to the second output of the current mirror, a third terminal and a fourth terminal;
a die ring circuitry disposed at edges of the semiconductor die, comprising:
a first plurality of segments disposed on a first leg of the die ring circuitry, and
a second plurality of segments disposed on a second leg of the die ring circuitry,
wherein the first and second legs having a same number of segments and are symmetrical on the die ring circuitry, and wherein the third terminal of the swap circuit is connected to the first leg and the fourth terminal of the swap circuit is connected to the second leg;
a voltage comparator including a positive input terminal, a negative input terminal and an output terminal, the negative input terminal being connected to the first output of the current mirror and the first terminal of the swap circuit; and
an adjustable resistor having a first terminal connected to the second terminal of the swap circuit, and a second terminal connected to the positive input terminal of the voltage comparator and the second output of the current mirror.

2. The semiconductor die defect detection device of claim 1, wherein the current mirror includes a current mirror core connected to a first voltage supply.

3. The semiconductor die defect detection device of claim 2, further comprising a feedback amplifier, the feedback amplifier having a negative input terminal electrically connected to the second output of the current mirror and a positive input terminal connected to a second voltage supply.

4. The semiconductor die defect detection device of claim 3, wherein the first voltage supply is configured to provide a first voltage close to 1.2V and the second voltage supply is configured to provide a second voltage close to 0.5V.

5. The semiconductor die defect detection device of claim 1, wherein the swap circuit includes a multiplexer configured to adjust interconnections between a first pair of the first terminal and the second terminal and a second pair of the third terminal and the fourth terminal.

6. The semiconductor die defect detection device of claim 5, wherein the first terminal of the swap circuit is electrically connected with the third terminal of the swap circuit, wherein the second terminal of the swap circuit is electrically connected with the fourth terminal of the swap circuit, and wherein the adjustable resistor is connected in serial with the second plurality of segments.

7. The semiconductor die defect detection device of claim 5, wherein the first terminal of the swap circuit is electrically connected with the fourth terminal of the swap circuit, wherein the second terminal of the swap circuit is electrically connected with the third terminal of the swap circuit, and wherein the adjustable resistor is connected in serial with the first plurality of segments.

8. The semiconductor die defect detection device of claim 1, wherein the adjustable resistor is made of passive elements in incremental values and has a resistance ranging from 1K ohms to 100K ohms or ranging from 0.5% to 40% of resistance of corresponding segment.

9. The semiconductor die defect detection device of claim 1, wherein each segment of the first plurality of segments and the second plurality of segments connects to a corresponding stage logic block, each of the stage logic blocks including a latch circuit, a pull down circuit, and an isolation circuit.

10. The semiconductor die defect detection device of claim 3, further comprising one or more flip-flop circuits or memories electrically connected to the output terminal of the voltage comparator and configured to store output signals generated from the voltage comparator.

11. The semiconductor die defect detection device of claim 10, further comprising a digital clock signal line, an analog route signal line, and a digital enable signal line, each of the digital clock signal line, the analog route signal line, and the digital enable signal line corresponds to a conductive path through one or more physical layers of the semiconductor die.

12. The semiconductor die defect detection device of claim 11, further comprising a swap signal input terminal on the swap circuit, a sensitivity adjustment terminal on the feedback amplifier, a clock signal input on the one or more flip-flop circuits, and a state machine input.

13. A semiconductor die defect detection device, comprising:
a first half segment line and a second half segment line disposed on edges of a semiconductor die, each of the first half and second half segment lines being connected with a test segment circuit;
a current mirror having a first current output terminal connected to the first half segment line and a second current output terminal connected to the second half segment line;
a swap circuit connected to the first half segment line and the second half segment line;
an adjustable resistor connected to one of the first half segment line and the second half segment line through the swap circuit; and
a voltage comparator electrically connected to the first half segment line and the second half segment line through the swap circuit, wherein a positive input terminal of the voltage comparator is connected to the adjustable resistor.

14. A method for semiconductor die defect detection, comprising:
pre-conditioning a semiconductor die defect detection device;
conducting a first comparison of resistances of a first plurality of segments and a second plurality of segments of the semiconductor die, wherein the first and the second plurality of segments are symmetrically disposed on the semiconductor die;
swapping an interconnection of an adjustable resistor between the first plurality of segments and the second plurality of segments of the semiconductor die;
conducting a second comparison of resistances of the first plurality of segments and the second plurality of segments of the semiconductor die; and
serially outputting the first comparison and second comparison results into digital high pulses or digital low pulses.

15. The method of claim 14, wherein pre-conditioning the semiconductor die defect detection device comprises:
turning on pull down circuits connected to the first plurality of segments and the second plurality of segments of the semiconductor die;
adjusting an enabling signal line connected to the first plurality of segments and the second plurality of segments of the semiconductor die to a high state; and
converting an output of a voltage comparator connected to the first plurality of segments and the second plurality of segments of the semiconductor die to a low state.

16. The method of claim 15, wherein conducting the first comparison of resistances comprises:
setting the adjustable resistor to a first resistance,
connecting the adjustable resistor with the second plurality of segments of the semiconductor die,
applying mirrored currents respectively to the first plurality of segments and the second plurality of segments, and
inputting a first voltage applied on the first plurality of segments to a negative input terminal of the voltage comparator and inputting a second voltage applied on the adjustable resistor and the second plurality of segments to a positive input terminal of the voltage comparator.

17. The method of claim 16, wherein conducting the second comparison of resistances comprises:
connecting the adjustable resistor with the first plurality of segments of the semiconductor die,
applying mirrored currents respectively to the first plurality of segments and the second plurality of segments, and
inputting a third voltage applied on the adjustable resistor and the first plurality of segments to the positive input terminal of the voltage comparator and inputting a fourth voltage applied on the second plurality of segments to the negative input terminal of the voltage comparator.

18. The method of claim 17, further comprising storing the first comparison and second comparison results in one or more flip-flop circuits or memories connected to an output terminal of the voltage comparator.

19. The method of claim 18, further comprised determining a defect on the semiconductor die in accordance with a low state of the voltage comparator output and the interconnection of the adjustable resistor to the first plurality of segments or the second plurality of segments of the semiconductor die.

20. The method of claim 14, further comprising sequentially processing method claims 16 to 19 via a state machine and by adjusting the resistance of the adjustable resistor.
